(19) United States
(12) Patent Application Publication
(10) Pub. No.: US 2024/0123827 A1
(43) Pub. Date: Apr. 18, 2024

(54) APPARATUS FOR CONTROLLING A VEHICLE, SYSTEM HAVING THE SAME AND METHOD FOR MONITORING THEREOF

(71) Applicants: HYUNDAI MOTOR COMPANY, SEOUL (KR); KIA CORPORATION, SEOUL (KR)

(72) Inventors: Geon Woo Park, Seoul (KR); Young Tae Ko, Gwangmyeong-si (KR); Hyeon Jun Kim, Gunpo-si (KR); Byung Mo Kang, Gwacheon-si (KR); Jong Seo Yoon, Incheon (KR)

(21) Appl. No.: 18/300,835

(22) Filed: Apr. 14, 2023

(30) Foreign Application Priority Data
Oct. 12, 2022 (KR) 10-2022-0130684

(51) Int. Cl. B60L 3/00; B60L 58/18; G01R 31/367; G01R 31/382; H01M 10/48

(52) U.S. Cl. CPC B60L 3/0046; B60L 58/18; G01R 31/367; G01R 31/382; H01M 10/482; B60L 2240/547; H01M 2010/4271

(57) ABSTRACT

A high-voltage battery control apparatus includes a plurality of high-voltage battery controllers configured to respectively monitor states of a plurality of high-voltage batteries included in one high-voltage battery pack depending on a predetermined period for monitoring the high-voltage battery pack, wherein the high-voltage battery controllers are configured to transition state of the plurality of high-voltage battery controllers together to an end state when a high-voltage battery controller among the high-voltage battery controllers, which has completed a monitoring operation, first waits until all monitoring operations of the high-voltage battery controllers that have not yet completed monitoring operations are completed and then all the monitoring operations of the high-voltage battery controllers are completed.

### CROSS REFERENCE TO RELATED APPLICATIONS

This application claims priority to and the benefit of Korean Patent Application No. 10-2022-0130684, filed in the Korean Intellectual Property Office on Oct. 12, 2022, the entire contents of which are incorporated herein by reference.

### BACKGROUND

### (a) Field of the Disclosure

The present disclosure relates to a high-voltage battery control apparatus, a system including the same and a monitoring method thereof, and more particularly, to a technique for preventing a monitoring error of a plurality of high-voltage battery packs.

### (b) Description of the Related Art

An eco-friendly vehicle such as an electric vehicle or a hydrogen vehicle uses a high-voltage battery to drive a motor. Therefore, safety of the high-voltage battery is a most important factor, and it monitors a state of the battery after ignition is turned off.

In particular, a commercial vehicle such as a hydrogen truck uses a plurality of battery packs because it requires a high power unlike a passenger vehicle, and each battery is monitored by a battery management system (BMS) when starting off.

It has a plurality of controllers for monitoring a plurality of battery packs, and each controller counts time by itself by a plurality of real time clocks (RTC) (computer internal clock), to perform monitoring of the high-voltage battery while repeating 4-hour sleep and 2-minute wake up for 2.5 days.

However, unlike passenger vehicles that use 1 pack of high-voltage battery packs, for commercial vehicles using multiple high-voltage battery packs, a dark current increases because a controller fails to enter a standby state depending on different timing of each controller due to RTC quality deviation during monitoring, thereby increasing a risk of discharging a 24V low voltage battery.

The above information disclosed in this Background section is only for enhancement of understanding of the background of the disclosure, and therefore, it may contain information that does not form the prior art that is already known to a person of ordinary skill in the art.

### SUMMARY

An exemplary embodiment of the present disclosure has been made in an effort to provide a high-voltage battery control apparatus, a system including the same and a monitoring method thereof, capable of continuously monitoring a plurality of high-voltage battery packs even when an internal timer error occurs due to quality deviation of the high-voltage battery packs, thereby preventing vehicle discharge due to an excessive dark current.

The technical objects of the present disclosure are not limited to the objects mentioned above, and other technical objects not mentioned may be clearly understood by those skilled in the art from the description of the claims.

An exemplary embodiment of the present disclosure provides a high-voltage battery control apparatus configured to include a plurality of high-voltage battery controllers configured to respectively monitor states of a plurality of high-voltage batteries included in one high-voltage battery pack depending on a predetermined period for monitoring the high-voltage battery pack, wherein the high-voltage battery controllers are configured to transition state of the plurality of high-voltage battery controllers together to an end state when a high-voltage battery controller among the high-voltage battery controllers, which has completed a monitoring operation, first waits until all monitoring operations of the high-voltage battery controllers that have not yet completed monitoring operations are completed and then all the monitoring operations of the high-voltage battery controllers are completed.

In an exemplary embodiment of the present disclosure, the high-voltage battery controllers may include a first high-voltage battery controller configured to monitor a state of a first high-voltage battery among the high-voltage batteries, a second high-voltage battery controller configured to monitor a state of a second high-voltage battery among the high-voltage batteries, and a third high-voltage battery controller configured to monitor a state of a third high-voltage battery among the high-voltage batteries.

In an exemplary embodiment of the present disclosure, the high-voltage battery controller may be configured to perform a primary function, and when a monitoring operation of the first high-voltage battery controller is completed, to determine whether monitoring operations of the second high-voltage battery controller and the third high-voltage battery controller have been completed.

In an exemplary embodiment of the present disclosure, the high-voltage battery controller may be configured to end the monitoring operation of the first high-voltage battery controller when the monitoring operations of the first high-voltage battery controller, the second high-voltage battery controller, and the third high-voltage battery controller are completed, and to transmits an end command for ending the monitoring operation to the second high-voltage battery controller and the third high-voltage battery controller.

In an exemplary embodiment of the present disclosure, the second high-voltage battery controller and the third high-voltage battery controller may transition to the end state upon receiving an end command signal for ending the monitoring operation from the high-voltage battery controller even when the monitoring operations of the high-voltage battery controller and the high-voltage battery controller are completed.

In an exemplary embodiment of the present disclosure, when all of the high-voltage battery controllers are in a standby state, when the second high-voltage battery controller, the third high-voltage battery controller, and the first high-voltage battery controller wake up in that order to perform a monitoring operation for a same time, the second high-voltage battery controller may be configured to wait until an end command is received from the first high-voltage battery controller after a monitoring operation of the second high-voltage battery controller is completed, and the third high-voltage battery controller may wait until an end command is received from the first high-voltage battery controller after a monitoring operation of the third high-voltage battery controller is completed.

In an exemplary embodiment of the present disclosure, the first high-voltage battery controller may be configured to determine whether the monitoring operations of the second high-voltage battery controller and the third high-voltage battery controller are completed after the monitoring operation of the first high-voltage battery controller is completed, and to transmit an end command to the second high-voltage battery controller and the third high-voltage battery controller when the monitoring operations of the second high-voltage battery controller and the third high-voltage battery controller are completed, and the monitoring operations of the first high-voltage battery controller, the second high-voltage battery controller, and the third high-voltage battery controller are simultaneously transitioned to an end state.

In an exemplary embodiment of the present disclosure, the high-voltage battery controllers may be configured to repeat a process of turning off a vehicle, then monitoring states of the high-voltage batteries for a first predetermined time, then waiting for the first time, and then performing monitoring for a second predetermined time, and waiting for a predetermined third time, and then performing monitoring for the second time, for a predetermined period.

An exemplary embodiment of the present disclosure provides a system including a high-voltage battery pack configured to include a plurality of high-voltage batteries, a high-voltage battery control apparatus configured to include a plurality of high-voltage battery controllers corresponding to the high-voltage batteries and monitoring states of the high-voltage batteries, and a battery management device configured to receive and manage a monitoring result of the high-voltage battery pack, wherein the high-voltage battery controllers may be configured to transition state of the plurality of high-voltage battery controllers together to an end state when a high-voltage battery controller among the high-voltage battery controllers, which has completed a monitoring operation, first waits until all monitoring operations of the high-voltage battery controllers that have not yet completed monitoring operations are completed and then all the monitoring operations of the high-voltage battery controllers are completed.

In an exemplary embodiment of the present disclosure, the system may further include a communication module configured to receive a monitoring result of the high-voltage battery pack from the battery management device and to transmit the monitoring result of the high-voltage battery pack to an external server when a problem occurs in the high-voltage battery pack.

In an exemplary embodiment of the present disclosure, the system may further include a server configured to transmit a notification to a user and to limit driving of the vehicle when receiving a result of occurrence of the problem of the high-voltage battery pack from the communication module.

In an exemplary embodiment of the present disclosure, the high-voltage battery controllers may be configured to repeat a process of turning off a vehicle, then monitoring states of the high-voltage batteries for a first predetermined time, then waiting for the first time, and then performing monitoring for a second predetermined time, and waiting for a predetermined third time, and then performing monitoring for the second time, for a predetermined period.

In an exemplary embodiment of the present disclosure, the high-voltage battery controllers may include a first high-voltage battery controller configured to monitor a state of a first high-voltage battery among the high-voltage batteries; a second high-voltage battery controller configured to monitor a state of a second high-voltage battery among the high-voltage batteries; and a third high-voltage battery controller configured to monitor a state of a third high-voltage battery among the high-voltage batteries.

In an exemplary embodiment of the present disclosure, the high-voltage battery controller may be configured to perform a primary function, and when a monitoring operation of the first high-voltage battery controller is completed, to determine whether monitoring operations of the second high-voltage battery controller and the third high-voltage battery controller have been completed.

In an exemplary embodiment of the present disclosure, the high-voltage battery controller may be configured to end the monitoring operation of the first high-voltage battery controller when the monitoring operations of the first high-voltage battery controller, the second high-voltage battery controller, and the third high-voltage battery controller are completed, and to transmits an end command for ending the monitoring operation to the second high-voltage battery controller and the third high-voltage battery controller.

An exemplary embodiment of the present disclosure provides a high-voltage battery monitoring method including waiting, by a high-voltage battery controller that has completed a monitoring operation first among a plurality of high-voltage battery controllers corresponding to a plurality of high-voltage batteries included in one high-voltage battery pack, until all monitoring operations of the high-voltage battery controllers that have not yet completed the monitoring operations are completed, and transitioning, by the high-voltage battery controller that has completed the monitoring operation first, the monitoring operations of the high-voltage battery controllers together to an end state when the monitoring operations of the high-voltage battery controllers are completed.

In an exemplary embodiment of the present disclosure, the high-voltage battery controllers include a first high-voltage battery controller configured to monitor a state of a first high-voltage battery among the high-voltage batteries, a second high-voltage battery controller configured to monitor a state of a second high-voltage battery among the high-voltage batteries, and a third high-voltage battery controller configured to monitor a state of a third high-voltage battery among the high-voltage batteries.

In an exemplary embodiment of the present disclosure, the waiting until all monitoring operations of the high-voltage battery controllers are completed may include performing a primary function, by the first high-voltage battery controller, and when a monitoring operation of the first high-voltage battery controller is completed, determining whether monitoring operations of the second high-voltage battery controller and the third high-voltage battery controller have been completed.

In an exemplary embodiment of the present disclosure, the waiting until all monitoring operations of the high-voltage battery controllers are completed may further include ending the monitoring operation of the first high-voltage battery controller when the monitoring operations of the first high-voltage battery controller, the second high-voltage battery controller, and the third high-voltage battery controller are completed.

In an exemplary embodiment of the present disclosure, the waiting until all monitoring operations of the high-voltage battery controllers are completed may further include transmitting an end command for ending the monitoring operation to the second high-voltage battery controller and the third high-voltage battery controller.

In an exemplary embodiment of the present disclosure, the transitioning of the monitoring operations of the high-voltage battery controllers together to the end state may include transitioning, by the second high-voltage battery controller and the third high-voltage battery controller, to the end state upon receiving an end command signal for ending the monitoring operation from the first high-voltage battery controller even when the monitoring operations of the second high-voltage battery controller and the third high-voltage battery controller are completed.

According to the present technique, it is possible to continuously monitor a plurality of high-voltage battery packs even when an internal timer error occurs due to quality deviation of the high-voltage battery packs, thereby preventing vehicle discharge due to an excessive dark current.

Furthermore, various effects that can be directly or indirectly identified through this document may be provided.

### BRIEF DESCRIPTION OF THE FIGURES

FIG. 1 illustrates a block diagram showing a configuration of a system including a high-voltage battery control apparatus according to an exemplary embodiment of the present disclosure.

FIG. 2 illustrates a detailed schematic diagram of a high-voltage battery controller according to an exemplary embodiment of the present disclosure.

FIG. 3 illustrates a view for describing monitoring scheduling of a high-voltage battery control apparatus according to an exemplary embodiment of the present disclosure.

FIG. 4 illustrates a system for a high-voltage battery control according to an exemplary embodiment of the present disclosure.

FIG. 5 illustrates a flowchart for describing a high-voltage battery monitoring method according to an exemplary embodiment of the present disclosure.

FIG. 6 illustrates a flowchart showing a method for monitoring each high-voltage battery controller according to an exemplary embodiment of the present disclosure.

FIG. 7 illustrates a view for describing an example in which a monitoring period of a plurality of high-voltage battery packs is shifted according to an exemplary embodiment of the present disclosure.

FIGS. 8, 9 and 10 each illustrate a view for describing an example of preventing a case in which a monitoring period of a plurality of high-voltage battery packs is shifted according to an exemplary embodiment of the present disclosure.

FIG. 11 illustrates an exemplary view for scheduling monitoring of a plurality of high-voltage battery packs according to an exemplary embodiment of the present disclosure.

FIG. 12 illustrates a computing system according to an exemplary embodiment of the present disclosure.

### DETAILED DESCRIPTION

Hereinafter, some exemplary embodiments of the present disclosure will be described in detail with reference to exemplary drawings. It should be noted that in adding reference numerals to constituent elements of each drawing, the same constituent elements have the same reference numerals as possible even though they are indicated on different drawings. Furthermore, in describing exemplary embodiments of the present disclosure, when it is determined that detailed descriptions of related well-known configurations or functions interfere with understanding of the exemplary embodiments of the present disclosure, the detailed descriptions thereof will be omitted.

In describing constituent elements according to an exemplary embodiment of the present disclosure, terms such as first, second, A, B, (a), and (b) may be used. These terms are only for distinguishing the constituent elements from other constituent elements, and the nature, sequences, or orders of the constituent elements are not limited by the terms. Furthermore, all terms used herein including technical scientific terms have the same meanings as those which are generally understood by those skilled in the technical field to which an exemplary embodiment of the present disclosure pertains (those skilled in the art) unless they are differently defined. Terms defined in a generally used dictionary shall be construed to have meanings matching those in the context of a related art, and shall not be construed to have idealized or excessively formal meanings unless they are clearly defined in the present specification.

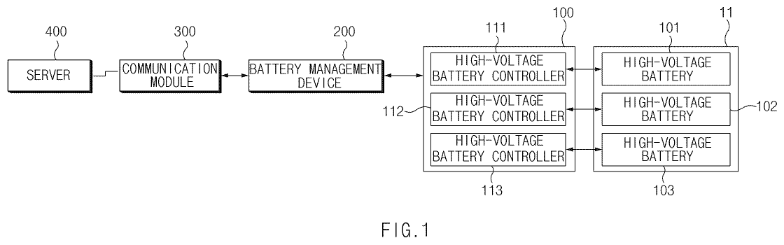

Hereinafter, various exemplary embodiments of the present disclosure will be described in detail with reference to FIG. 1 to FIG. 12.

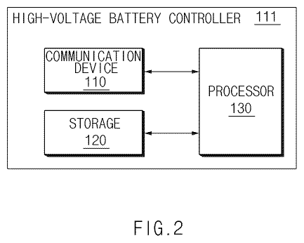

FIG. 1 illustrates a block diagram showing a configuration of a vehicle system 10 including a high-voltage battery control apparatus according to an exemplary embodiment of the present disclosure, and FIG. 2 illustrates a detailed schematic diagram of a high-voltage battery controller according to an exemplary embodiment of the present disclosure.

Referring to FIG. 1, the vehicle system 10 for monitoring a high-voltage battery pack according to an exemplary embodiment of the present disclosure includes a high-voltage battery pack 11, a high-voltage battery control apparatus 100, a battery management device 200, and a communication module 300, and when an abnormality occurs in the high-voltage battery pack 11, may transmit a result thereof to a server 400.

The high-voltage battery pack 11 may include one or more high-voltage batteries 101, 102, and 103, and the high-voltage battery control apparatus 100 may include high-voltage battery controllers 111, 112, and 113 for monitoring the respective high-voltage batteries 101, 102, and 103.

FIG. 1 discloses an example in which the high-voltage battery pack 11 including three high-voltage batteries 101, 102, and 103, but the present disclosure is not limited thereto, and may include a larger number of high-voltage batteries, and accordingly, the number of high-voltage battery controllers may be increased.

The high-voltage battery pack 11 and the high-voltage battery control apparatus 100 may be configured as one package, and the high-voltage battery controllers 111, 112, and 113 may monitor states of the high-voltage batteries 101, 102, and 103, respectively, to transmit them to the battery management device 200.

The high-voltage battery controllers 111, 112, and 113 may be integrally formed with internal control units of the vehicle, or may be implemented as a separate hardware device to be connected to control units of the vehicle by a connection means. As an example, the high-voltage battery controller 111, 112, and 113 may be implemented integrally with the high-voltage battery 101, 102, and 103, may be implemented in a form that is installed and attached to the high-voltage battery 101, 102, and 103 as a configuration that is separate from the high-voltage battery 101, 102, and 103, or some thereof may be implemented integrally with the high-voltage batteries 101, 102, 103, and may be implemented in a form that is installed and attached to the high-voltage batteries 101, 102, and 103 as a separate configuration from the high-voltage batteries 101, 102, and 103.

The high-voltage battery controllers 111, 112, and 113 may each include a battery management unit (BMU), and for convenience, may be named as a first high-voltage battery controller BMU1, a second high-voltage battery controller BMU2, and a third high-voltage battery controller BMU3. The high-voltage battery controller 111 may be a primary controller, and the remaining high-voltage battery controllers 112 and 113 may be secondary controllers.

The battery management device 200 may be implemented as a battery management system (BMS), and may receive state information of the respective high-voltage batteries 101, 102, and 103 from the high-voltage battery controllers 111, 112, and 113.

The high-voltage battery controllers 111, 112, and 113 may include a communication device 110, a storage 120, and a processor 130. Although only the high-voltage battery controller 111 is illustrated in FIG. 2, detailed configurations of the high-voltage battery controllers 112 and 113 are also the same as that of the high-voltage battery controller 111, so a separate disclosure will be omitted.

The communication device 110 is a hardware device implemented with various electronic circuits to transmit and receive signals through a wireless or wired connection, and may transmit and receive information based on in-vehicle devices and in-vehicle network communication techniques. As an example, the in-vehicle network communication techniques may include controller area network (CAN) communication, local-CAN communication, local interconnect network (LIN) communication, flex-ray communication, and the like.

As an example, the communication device 110 may transmit a monitoring result of the high-voltage battery 101 to the battery management device 200.

The storage 120 may store data and/or algorithms required for the processor 130 to operate, and the like. As an example, the storage 120 may include period information for monitoring the high-voltage battery 101.

The storage 120 may include a storage medium of at least one type among memories of types such as a flash memory, a hard disk, a micro, a card (e.g., a secure digital (SD) card or an extreme digital (XD) card), a random access memory (RAM), a static RAM (SRAM), a read-only memory (ROM), a programmable ROM (PROM), an electrically erasable PROM (EEPROM), a magnetic memory (MRAM), a magnetic disk, and an optical disk.

Although not illustrated in FIG. 2, the high-voltage battery controllers 111, 112, and 113 may each have a built-in timer for a monitoring period.

The processor 130 may be electrically connected to the communication device 110, the storage 120, and the like, may electrically control each component, and may be an electrical circuit that executes software commands, thereby performing various data processing and calculations described below.

The processor 130 may perform overall control such that each component can normally perform their functions by processing a signal transferred between each component of the high-voltage battery controller 111. The processor 130 may be implemented in the form of hardware, software, or a combination of hardware and software. For example, the processor 130 may be implemented as a microprocessor, but the present disclosure is not limited thereto.

Hereinafter, an operation performed by each of the high-voltage battery controller (first high-voltage battery controller, 111), high-voltage battery controller (second high-voltage battery controller, 112), and high-voltage battery controller (third high-voltage battery controller, 113) may be described as being driven by the processor 130 in each of the controllers.

The high-voltage battery controller 111 performs a master function, and when the monitoring operation of the high-voltage battery controller 111 is completed, may determine whether monitoring operations of the high-voltage battery controller 112 and the third high-voltage battery controller are completed.

When the monitoring operations of the high-voltage battery controller 111, the high-voltage battery controller 112, and the high-voltage battery controller 113 are completed, the high-voltage battery controller 111 may end the monitoring operation of the high-voltage battery controller 111, and may transmit an end command to end the monitoring operation to the high-voltage battery controller 112 and the third high-voltage battery controller 113.

The high-voltage battery controller 112 and the high-voltage battery controller 113 may transition to an end state upon receiving an end command signal for ending the monitoring operation from the high-voltage battery controller even when the monitoring operations of the high-voltage battery controller and the high-voltage battery controller are completed.

After the monitoring operation of the high-voltage battery controller 111 is completed, the high-voltage battery controller 111 may determine whether the monitoring operations of the high-voltage battery controller 112 and the high-voltage battery controller 113 are completed, and when the monitoring operations of the high-voltage battery controller 112 and the high-voltage battery controller 113 are completed, may transmit an end command to the high-voltage battery controller 112 and the high-voltage battery controller 113.

Monitoring operations of the high-voltage battery controller 111, the high-voltage battery controller 112, and the third high-voltage battery controller may simultaneously transition to an end state.

The high-voltage battery controllers 111, 112, and 113 may repeat a process of turning off the vehicle, then monitoring states of the high-voltage batteries for a first predetermined time (e.g., 2 hours), then waiting for the first time, and then performing monitoring for a second predetermined time (e.g., 2 minutes), and waiting for a predetermined third time (e.g. 4 hours), and then performing monitoring for the second time, for a predetermined period (e.g., 2.5 days).

In FIG. 1 and FIG. 2, an example in which each of the high-voltage battery controllers 111, 112, and 113 controls a monitoring period based on an internal timer is disclosed, but the present disclosure is not limited thereto, and the battery management device 200 may perform monitoring by controlling the monitoring period of the high-voltage battery controllers 111, 112, and 113.

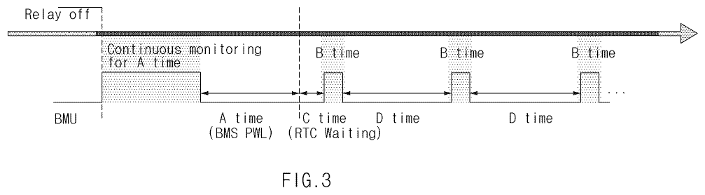

FIG. 3 illustrates a view for describing monitoring scheduling of a high-voltage battery control apparatus according to an exemplary embodiment of the present disclosure.

Referring to FIG. 3, the high-voltage battery controllers 111, 112, and 113 perform continuous monitoring for each of the respective high-voltage batteries 101, 102, and 103 for an A time (e.g., 2 hours) after turning off (relay off) the vehicle, and performs continuous monitoring for the respective high-voltage battery 101, 102, and 103 for a B time (e.g., 2 minutes) after waiting for the A time, and waiting for additional a C time (e.g., 1 minute). Thereafter, the high-voltage battery controllers 111, 112, and 113 perform a process of continuously monitoring the respective high-voltage battery 101, 102, and 103 for the B time after waiting for the D time (e.g., 4 hours), for a predetermined period (e.g., 2.5 days).

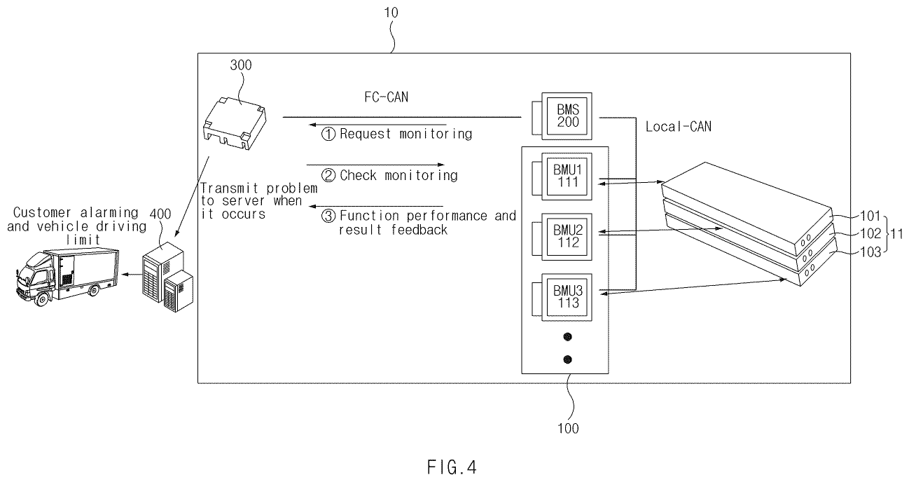

FIG. 4 illustrates a system for high-voltage battery management according to an exemplary embodiment of the present disclosure.

Referring to FIG. 4, the vehicle system 10 may monitors a state of the high-voltage battery pack 11 and may transmit it to the server 400 when a problem (e.g., an SOC (state of charge) abnormality, temperature abnormality, etc. of the high-voltage batteries) occurs, and the server 400 may transmit an alarm to the customer or may limit the driving of the vehicle.

The vehicle system 10 may include a high-voltage battery pack 11, a high-voltage battery control apparatus 100, a battery management device 200, and a communication module 300.

The battery management device 200 may periodically communicate with the high-voltage battery control apparatus 100 to receive a state result of the high-voltage battery pack 11 to transmit the state result to the communication module 300.

When the communication module 300 receives a monitoring request from the battery management device 200, the communication module 300 transmits a feedback signal confirming that monitoring is started to the battery management device 200.

In addition, the communication module 300 may communicate with the external server 400, and when a problem occurs with the high-voltage battery pack based on a monitoring result of the high-voltage battery pack 11, may transmit a result to the external server 400. The communication module 300 may transmit a notification to the user when a problem situation of the high-voltage battery pack occurs.

For example, the communication module 300 may include a telematics terminal, audio, video, navigation (AVN), a navigation device, and the like.

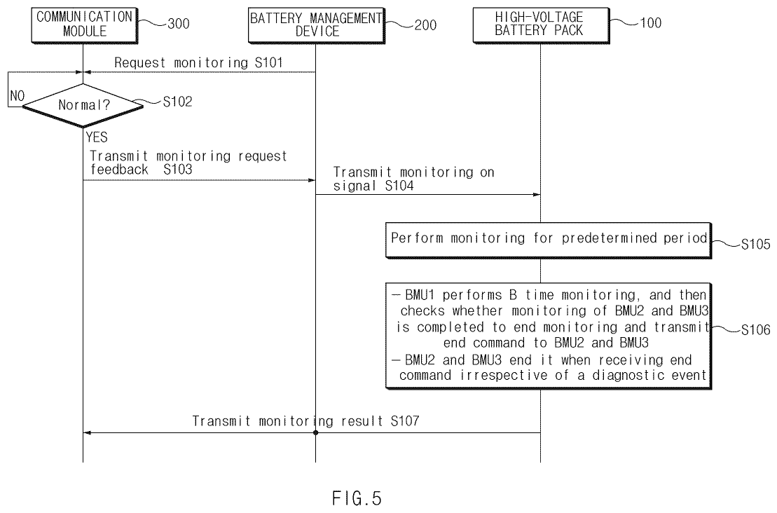

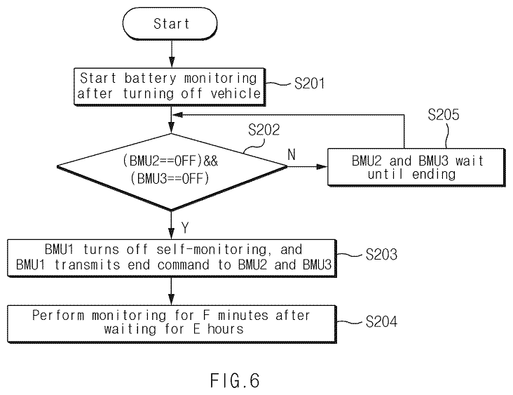

Hereinafter, a high-voltage battery monitoring method according to an exemplary embodiment of the present disclosure will be described in detail with reference to FIG. 5 and FIG. 6. FIG. 5 illustrates a flowchart for describing a high-voltage battery monitoring method according to an exemplary embodiment of the present disclosure, and FIG. 6 illustrates a flowchart showing a method for monitoring each high-voltage battery controller according to an exemplary embodiment of the present disclosure.

Hereinafter, it is assumed that the system 10 of FIG. 1 performs a process of FIG. 5. Referring to FIG. 5, the battery management device 200 requests monitoring from the communication module 300 through a FC-CAN communication network at S101.

Accordingly, the communication module 300 determines whether its communication function is in a normal state at S102, and when the communication function is in the normal state, transmits a feedback signal for the monitoring request to the battery management device 200 at S103, and the feedback signal for the monitoring request may include a monitoring start signal as a response to the monitoring request.

Accordingly, the battery management device 200 transmits a monitoring ON signal to the high-voltage battery control device 100 at S104.

Accordingly, the high-voltage battery control device 100 performs monitoring for a predetermined period by itself at S105.

That is, the high-voltage battery controllers BMU1 (111) in the high-voltage battery control device 100 check whether monitoring of other high-voltage battery controllers BMU2 (112) and BMU3 (113) is completed after performing monitoring for a B time for each RTC cycle. Accordingly, when the monitoring of other high-voltage battery controllers BMU2 and BMU3 is completed, the high-voltage battery controller BMU1 may transmit a result of its monitoring and an end command for allowing the high-voltage battery controllers BMU2 and BMU3 to end monitoring to the high-voltage battery controllers BMU2 and BMU3.

In this case, the high-voltage battery controllers BMU2 and BMU3 perform the end when receiving the end command from the high-voltage battery controller BMU1 irrespective of a diagnostic event at S106.

Thereafter, the high-voltage battery control apparatus 100 transmits the monitoring result of the high-voltage battery pack to the communication module 300 through the battery management device 200 at S107.

Hereinafter, a high-voltage battery monitoring process will be described in more detail with reference to FIG. 6.

Hereinafter, it is assumed that the system 10 of FIG. 1 performs a process of FIG. 6. In addition, in the description of FIG. 6, operations described as being performed by a device may be understood as being controlled by the high-voltage battery controllers 111, 112, and 113 of the high-voltage battery control apparatus 100.

Referring to FIG. 6, after turning off the vehicle, the high-voltage battery controllers 111, 112, and 113 monitor the high-voltage batteries 101, 102, and 103 for a predetermined B time, respectively at S201.

Thereafter, when the monitoring of the high-voltage battery 101 is completed, the high-voltage battery controller 111 determines whether the monitoring operations of the remaining high-voltage battery controllers 112 and 113 are completed at S202.

When the monitoring operations of the high-voltage battery controllers 112 and 113 are completed, the high-voltage battery controller 111 ends self-monitoring and transmits an end command to the high-voltage battery controllers 112 and 113 at S203.

Accordingly, the high-voltage battery controllers 111, 112, and 113 stop performing monitoring at a same time, and after waiting for an E time, perform monitoring for F minutes at S204.

Meanwhile, in step S202, when the monitoring operation of the high-voltage battery controller 111 is completed but the monitoring operations of the remaining high-voltage battery controllers 112 and 113 are not completed, it waits until the monitoring operations of the remaining high-voltage battery controllers 112 and 113 are completed at S205, and then when the monitoring operations of the remaining high-voltage battery controllers 112 and 113 are completed, it performs steps S203 and S204.

Therefore, according to the present disclosure, monitoring may be continuously performed even when a timer error occurs due to quality deviation of the high-voltage battery pack while a monitoring function for detecting abnormality in a high-voltage battery of an eco-friendly vehicle is operating.

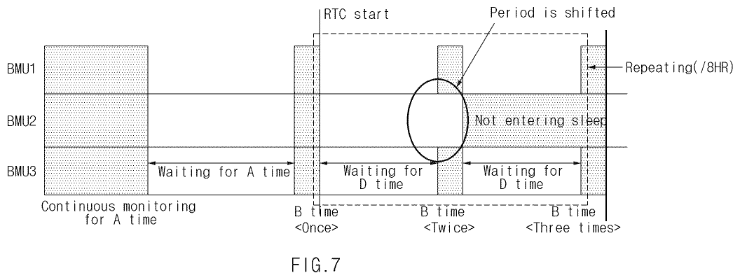

FIG. 7 illustrates a view for describing an example in which a monitoring period of a plurality of high-voltage battery packs is shifted according to an exemplary embodiment of the present disclosure.

Referring to FIG. 7, after turning off the vehicle, the high-voltage battery controllers BMU1, BMU2, and BMU3 each perform monitoring for a predetermined A time, wait for the A time, and then perform monitoring for a B time again. Thereafter, when performing monitoring again for the B time after waiting for a D time, the high-voltage battery controllers BMU1 and BMU3 normally waited for the D time and then monitored for the B time, but the high-voltage battery controller BMU2 continues to wait after waiting for the D time, and after the monitoring of the high-voltage battery controllers BMU1 and BMU3 for the B time is completed, the high-voltage battery controller BMU2 performs monitoring. Accordingly, the high-voltage battery controller BMU2 does not enter a standby mode even after the B time, and continues monitoring, thereby consuming power.

As such, when a battery monitoring cycle of each of the high-voltage battery controllers BMU1, BMU2, and BMU3 is out of line, variations in RTC quality of each of the high-voltage battery controllers BMU1, BMU2, and BMU3 may cause diagnostic delays, resulting in that a high-voltage battery controller does not enter a standby state, and thus current consumption in a parking state increases, which may cause battery discharge.

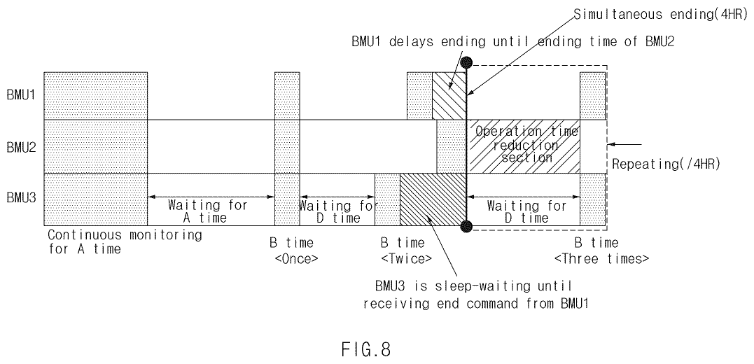

FIG. 8 to FIG. 10 each illustrate a view for describing an example of preventing a case in which a monitoring period of a plurality of high-voltage battery packs is shifted according to an exemplary embodiment of the present disclosure.

As illustrated in FIG. 7, an example for restoring a normal cycle when B time monitoring of the high-voltage battery controllers BMU1 and BMU3 is completed but B time monitoring of the high-voltage battery controller BMU2 is not performed, will be described with referring to FIG. 8.

The high-voltage battery controller BMU1 does not immediately end monitoring even when the B time monitoring is completed after waiting for an A time, but checks whether the B time monitoring of the high-voltage battery controllers BMU2 and BMU3 is completed through local CAN communication. Accordingly, the high-voltage battery controller BMU1 ends the monitoring of the high-voltage battery controller BMU1 after the B time monitoring of the high-voltage battery controller BMU2 and BMU3 is completed, and when the monitoring of the high-voltage battery controller BMU1 is ended, transmits an end command to the high-voltage battery controllers BMU2 and BMU3.

Accordingly, the high-voltage battery controller BMU1 delays end of monitoring for a certain period of time after completion of B time monitoring, and the high-voltage battery controller BMU3 completed the B time monitoring first, but waits without ending monitoring because no end command has been received from the high-voltage battery controller BMU1.

When the monitoring of the high-voltage battery controller BMU2 is completed, the high-voltage battery controller BMU1 ends its monitoring, and transmits an end command for a B time monitoring operation to the high-voltage battery controllers BMU2 and BMU3, and thus the high-voltage battery controllers BMU2 and BMU3 end their B time monitoring operation.

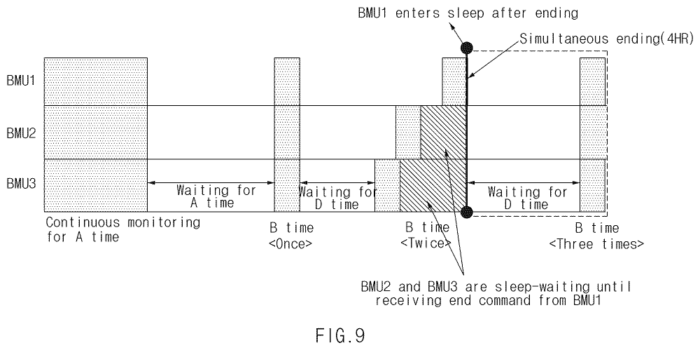

Referring to FIG. 9, a case in which the high-voltage battery controller BMU3, the high-voltage battery controller BMU2, and the high-voltage battery controller BMU1 wake up in order to perform B time monitoring due to an RTC timer problem.

That is, when the high-voltage battery controller BMU1 wakes up later than the high-voltage battery controllers BMU2 and BMU3, the high-voltage battery controllers BMU2 and BMU3 wait until an end command is received from the high-voltage battery controller BMU1.

Accordingly, when the high-voltage battery controller BMU1 ends B time monitoring and transmits an end command to the high-voltage battery controllers BMU2 and BMU3, the high-voltage battery controllers BMU1, BMU2, and BMU3 simultaneously repeat a process of completing the B time monitoring, then waiting for the D time and then performing the B time monitoring.

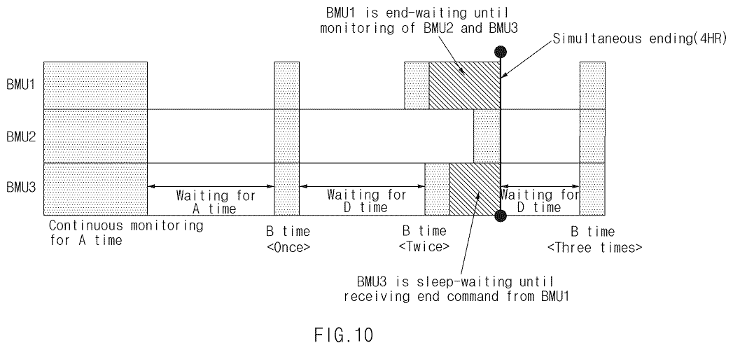

Referring to FIG. 10, a case in which the high-voltage battery controller BMU1, the high-voltage battery controller BMU3, and the high-voltage battery controller BMU2 wake up in order to perform B time monitoring due to an RTC timer problem.

That is, when the high-voltage battery controllers BMU1 and BMU3 wake up before the high-voltage battery controller BMU1, the high-voltage battery controllers BMU1 and BMU3 wait until the B time monitoring of the high-voltage battery controller BMU2 is completed.

Thereafter, when the B time monitoring of the high-voltage battery controller BMU2 is completed, the high-voltage battery controller BMU1 transmits an end command to the high-voltage battery controllers BMU2 and BMU3, and thus the high-voltage battery controllers BMU1, BMU2, and BMU3 simultaneously repeat a process of completing the B time monitoring, then waiting for the D time and then performing the B time monitoring.

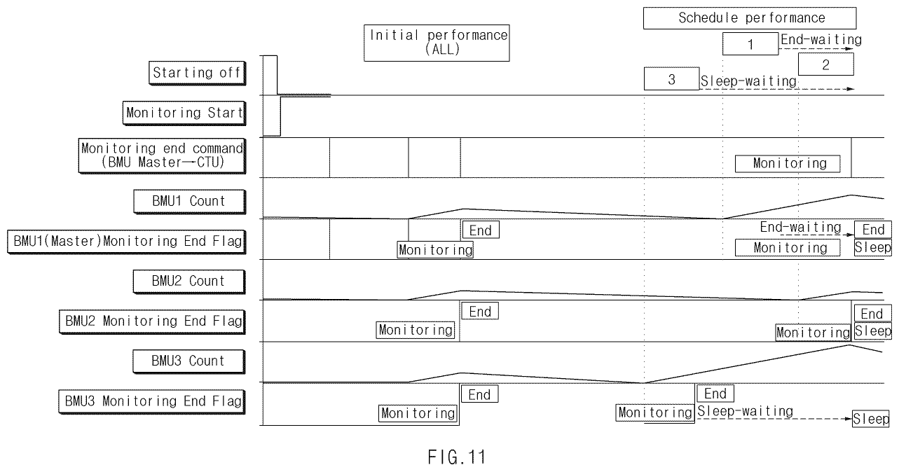

FIG. 11 illustrates an exemplary view for scheduling monitoring of a plurality of high-voltage battery packs according to an exemplary embodiment of the present disclosure.

Referring to FIG. 11, after turning off the vehicle, the high-voltage battery controllers BMU1, BMU2, and BMU3 monitor the vehicle for a certain period of time and then simultaneously end the monitoring. Thereafter, when monitoring is delayed due to a timer error of each of the high-voltage battery controllers BMU1, BMU2, and BMU3, the high-voltage battery controller, which wakes up first and completes monitoring first, waits to delay the end of monitoring until the last high-voltage battery controller that wakes up completes the monitoring, and thus the high-voltage battery controllers BMU1, BMU2, and BMU3 all simultaneously end their monitoring and move on to a next cycle.

As such, according to the present disclosure, to solve a problem that a battery controller discharges a 24-V battery due to continuous power consumption even after the vehicle is turned off due to an RTC (internal clock) error of each battery pack, even when an RTC error of the high-voltage battery pack occurs, a battery monitoring function is allowed to be normally performed by adding a control for each battery pack to monitor each other.

Accordingly, according to the present disclosure, vehicle discharge prevention due to an excessive dark current and high-voltage battery safety management may be performed by ensuring continuous monitoring even when an internal timer error occurs due to battery pack quality deviation while a high-voltage battery abnormality detection function of an eco-friendly vehicle is operating.

In addition, according to the present disclosure, a result of monitoring a state of the high-voltage battery may be analyzed, and when a problem occurs, the vehicle may be unable to start and a notification function is performed to a driver, increasing safety of an eco-friendly vehicle.

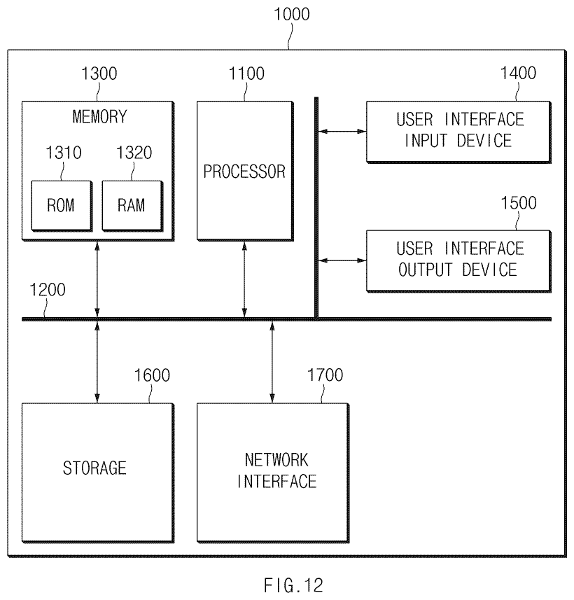

FIG. 12 illustrates a computing system according to an exemplary embodiment of the present disclosure.

Referring to FIG. 12, the computing system 1000 includes at least one processor 1100 connected through a bus 1200, a memory 1300, a user interface input device 1400, a user interface output device 1500, and a storage 1600, and a network interface 1700.

The processor 1100 may be a central processing unit (CPU) or a semiconductor device that performs processing on commands stored in the memory 1300 and/or the storage 1600. The memory 1300 and the storage 1600 may include various types of volatile or nonvolatile storage media. For example, the memory 1300 may include a read only memory (ROM) 1310 and a random access memory (RAM) 1320.

Accordingly, steps of a method or algorithm described in connection with the exemplary embodiments disclosed herein may be directly implemented by hardware, a software module, or a combination of the two, executed by the processor 1100. The software module may reside in a storage medium (i.e., the memory 1300 and/or the storage 1600) such as a RAM memory, a flash memory, a ROM memory, an EPROM memory, an EEPROM memory, a register, a hard disk, a removable disk, and a CD-ROM.

An exemplary storage medium is coupled to the processor 1100, which can read information from and write information to the storage medium. Alternatively, the storage medium may be integrated with the processor 1100. The processor and the storage medium may reside within an application specific integrated circuit (ASIC). The ASIC may reside within a user terminal. Alternatively, the processor and the storage medium may reside as separate components within the user terminal.

The above description is merely illustrative of the technical idea of the present disclosure, and those skilled in the art to which the present disclosure pertains may make various modifications and variations without departing from the essential characteristics of the present disclosure.

Therefore, the exemplary embodiments disclosed in the present disclosure are not intended to limit the technical ideas of the present disclosure, but to explain them, and the scope of the technical ideas of the present disclosure is not limited by these exemplary embodiments. The protection range of the present disclosure should be interpreted by the claims below, and all technical ideas within the equivalent range should be interpreted as being included in the scope of the present disclosure.

1. A high-voltage battery control apparatus comprising:
a high-voltage battery control apparatus including a plurality of high-voltage battery controllers, each of the plurality of high-voltage battery controllers being configured to monitor a state of a plurality of high-voltage batteries included in one high-voltage battery pack depending on a predetermined period for monitoring the high-voltage battery pack;
wherein each of the high-voltage battery controllers are further configured to transition a state of the plurality of high-voltage battery controllers together to an end state when one of the high-voltage battery controllers among the plurality of high-voltage battery controllers, which has completed a monitoring operation, first waits until all monitoring operations of the plurality of high-voltage battery controllers that have not yet completed monitoring operations are completed, and then all the monitoring operations of the plurality of high-voltage battery controllers are completed.

2. The high-voltage battery control apparatus of claim 1, wherein the plurality of high-voltage battery controllers includes:
a first high-voltage battery controller configured to monitor a state of a first high-voltage battery among the plurality of high-voltage batteries;
a second high-voltage battery controller configured to monitor a state of a second high-voltage battery among the plurality of high-voltage batteries; and
a third high-voltage battery controller configured to monitor a state of a third high-voltage battery among the plurality of high-voltage batteries.

3. The high-voltage battery control apparatus of claim 2, wherein the first high-voltage battery controller is configured to perform a master function, and when a monitoring operation of the first high-voltage battery controller is completed, to the first high-voltage battery controller is configured to determine whether monitoring operations of the second high-voltage battery controller and the third high-voltage battery controller have been completed.

4. The high-voltage battery control apparatus of claim 3, wherein the first high-voltage battery controller is configured to end the monitoring operation of the first high-voltage battery controller when the monitoring operations of the first high-voltage battery controller, the second high-voltage battery controller, and the third high-voltage battery controller are completed, and
wherein the first high-voltage batter controller is further configured to transmit an end command for ending the monitoring operation to the second high-voltage battery controller and the third high-voltage battery controller.

5. The high-voltage battery control apparatus of claim 3, wherein the second high-voltage battery controller and the third high-voltage battery controller, are configured to transition to an end state when receiving an end command signal for ending the monitoring operation from the first high-voltage battery controller even when the monitoring operations of the second high-voltage battery controller and the third high-voltage battery controller are completed.

6. The high-voltage battery control apparatus of claim 2, wherein when each of the plurality of high-voltage battery controllers are in a standby state,
when the second high-voltage battery controller, the third high-voltage battery controller, and the first high-voltage battery controller wake up in that order to perform a monitoring operation for a same time,
the second high-voltage battery controller is configured to wait until an end command is received from the first high-voltage battery controller after a monitoring operation of the second high-voltage battery controller is completed, and
the third high-voltage battery controller is configured to wait until an end command is received from the first high-voltage battery controller after a monitoring operation of the third high-voltage battery controller is completed.

7. The high-voltage battery control apparatus of claim 6, wherein the first high-voltage battery controller is configured to:
determine whether the monitoring operations of the second high-voltage battery controller and the third high-voltage battery controller are completed after the monitoring operation of the first high-voltage battery controller is completed; and
transmit an end command to the second high-voltage battery controller and the third high-voltage battery controller when the monitoring operations of the second high-voltage battery controller and the third high-voltage battery controller are completed; and
wherein the monitoring operations of the first high-voltage battery controller, the second high-voltage battery controller, and the third high-voltage battery controller are simultaneously transitioned to an end state.

8. The high-voltage battery control apparatus of claim 1, wherein the plurality of high-voltage battery controllers are configured to repeat a process of turning off a vehicle, then monitoring states of the plurality of high-voltage batteries for a first predetermined time, then waiting for the first time, and then performing monitoring for a second predetermined time, and waiting for a predetermined third time, and then performing monitoring for the second time, for a predetermined period.

9. A system comprising:
a high-voltage battery pack including a plurality of high-voltage batteries;
a high-voltage battery control apparatus including a plurality of high-voltage battery controllers corresponding to the plurality of high-voltage batteries, and configured to monitor states of the plurality of high-voltage batteries; and
a battery management device configured to receive and manage a monitoring result of the high-voltage battery pack;
wherein the high-voltage battery controllers are configured to transition a state of each of the plurality of high-voltage battery controllers to an end state when a high-voltage battery controller among the plurality of high-voltage battery controllers, which has completed a monitoring operation, first waits until all monitoring operations of the plurality of high-voltage battery controllers that have not yet completed monitoring operations are completed, and then all the monitoring operations of the plurality of high-voltage battery controllers are completed.

10. The system of claim 9, further comprising a communication module configured to receive a monitoring result of the high-voltage battery pack from the battery management device, and to transmit the monitoring result of the high-voltage battery pack to an external server when a problem occurs in the high-voltage battery pack.

11. The system of claim 10, further comprising a server configured to transmit a notification to a user and to limit driving of the vehicle when receiving a result of occurrence of the problem of the high-voltage battery pack from the communication module.

12. The system of claim 9, wherein the plurality of high-voltage battery controllers are configured to repeat a process of turning off a vehicle, then monitoring states of the high-voltage batteries for a first predetermined time, then waiting for the first time, and then performing monitoring for a second predetermined time, and waiting for a predetermined third time, and then performing monitoring for the second time, for a predetermined period.

13. The system of claim 9, wherein the plurality of high-voltage battery controllers includes:
a first high-voltage battery controller configured to monitor a state of a first high-voltage battery among the plurality of high-voltage batteries;
a second high-voltage battery controller configured to monitor a state of a second high-voltage battery among the plurality of high-voltage batteries; and
a third high-voltage battery controller configured to monitor a state of a third high-voltage battery among the plurality of high-voltage batteries.

14. The system of claim 13, wherein the first high-voltage battery controller is configured to:
perform a primary function, and when a monitoring operation of the first high-voltage battery controller is completed, the first high-voltage battery controller is configured to determine whether monitoring operations of the second high-voltage battery controller and the third high-voltage battery controller have been completed;
end the monitoring operation of the first high-voltage battery controller when the monitoring operations of the first high-voltage battery controller, the second high-voltage battery controller, and the third high-voltage battery controller are completed; and
transmit an end command for ending the monitoring operation to the second high-voltage battery controller and the third high-voltage battery controller.

15. A high-voltage battery monitoring method comprising:
waiting, by a high-voltage battery controller that has completed a monitoring operation first among a plurality of high-voltage battery controllers corresponding to a plurality of high-voltage batteries included in one high-voltage battery pack, until all monitoring operations of the plurality of high-voltage battery controllers that have not yet completed the monitoring operations are completed; and
transitioning, by the high-voltage battery controller that has completed the monitoring operation first, the monitoring operations of the plurality of high-voltage battery controllers together to an end state when the monitoring operations of the plurality of high-voltage battery controllers are completed.

16. The high-voltage battery monitoring method of claim 15, wherein the plurality of high-voltage battery controllers include:
a first high-voltage battery controller configured to monitor a state of a first high-voltage battery among the plurality of high-voltage batteries;
a second high-voltage battery controller configured to monitor a state of a second high-voltage battery among the plurality of high-voltage batteries; and
a third high-voltage battery controller configured to monitor a state of a third high-voltage battery among the plurality of high-voltage batteries.

17. The high-voltage battery monitoring method of claim 16, wherein the waiting until all monitoring operations of the plurality of high-voltage battery controllers are completed includes performing a master function, by the first high-voltage battery controller, and when a monitoring operation of the first high-voltage battery controller is completed, determining whether monitoring operations of the second high-voltage battery controller and the third high-voltage battery controller have been completed.

18. The high-voltage battery monitoring method of claim 17, wherein the waiting until all monitoring operations of the plurality of high-voltage battery controllers are completed further includes ending the monitoring operation of the first high-voltage battery controller when the monitoring operations of the first high-voltage battery controller, the second high-voltage battery controller, and the third high-voltage battery controller are completed.

19. The high-voltage battery monitoring method of claim 18, wherein the waiting until all monitoring operations of the plurality of high-voltage battery controllers are completed further includes transmitting an end command for ending the monitoring operation to the second high-voltage battery controller and the third high-voltage battery controller.

20. The high-voltage battery monitoring method of claim 19, wherein the transitioning of the monitoring operations of the plurality of high-voltage battery controllers together to the end state includes transitioning, by the second high-voltage battery controller and the third high-voltage battery controller, to the end state upon receiving an end command signal for ending the monitoring operation from the first high-voltage battery controller even when the monitoring operations of the second high-voltage battery controller and the third high-voltage battery controller are completed.
